(19) United States
(12) Patent Application Publication
(10) Pub. No.: US 2024/0322054 A1
(43) Pub. Date: Sep. 26, 2024

(54) Advanced UV Reference Photodiode

(71) Applicant: X-FAB Global Services GmbH, Erfurt (DE)

(72) Inventors: Daniel Gäbler, Apolda (DE); Pablo Siles, Erfurt (DE); Jotham Ong Hu Ngu, Kuching (MY); Qiang Ai, Kuching (MY); Tamer Abdulrahman, Évry (FR); Tong Hong Tan, Sarawak (MY)

(21) Appl. No.: 18/610,008

(22) Filed: Mar. 19, 2024

(30) Foreign Application Priority Data
Mar. 20, 2023 (GB) 2304001.7
Jul. 12, 2023 (GB) 2310724.6
Sep. 25, 2023 (GB) 2314622.8
Mar. 13, 2024 (GB) 2403638.6

(51) Int. Cl. H01L 31/0216; H01L 27/144; H01L 31/103; H01L 31/18

(52) U.S. Cl. CPC H01L 31/02164; H01L 27/1443; H01L 31/103; H01L 31/1868

(57) ABSTRACT

An optical UV sensor comprises:
a first photodiode sensitive to light in a first wavelength range and to light in a second wavelength range in the UV spectrum, wherein the second wavelength range comprises longer wavelengths than the first wavelength range, and wherein the first photodiode is configured to output a first signal in response to incident light;
a second photodiode sensitive to light in the second wavelength range and comprising an absorption layer having an optical thickness in the range of 10 nm to 250 nm to absorb light in the first wavelength range, while being substantially transparent to light in the second wavelength range, wherein the second photodiode is configured to output a second signal in response to incident light;
wherein the optical sensor is configured to output a difference between the first signal and the second signal.

### TECHNICAL FIELD

The invention relates photodiodes, and in particular to photodiodes having a high sensitivity in the ultraviolet range.

### BACKGROUND

Photodiodes are used in a wide range of applications for detecting and measuring electromagnetic radiation. It is known that a noise level of an output signal of a photodiode can be improved by subtracting the current of a dark reference device (a similar photodiode which is insensitive to light) from the current of the photodiode. The reference device may be made insensitive to incident light by covering the light sensitive area of the device with an opaque material (for example a metal layer). However, there is a continued need for improvements to the sensitivity and durability of photodiodes.

### SUMMARY

Aspects of the invention provide an optical sensor and a method of forming an optical sensor as set out in the accompanying claims.

Specific embodiments are described below with reference to the drawings,

### BRIEF DESCRIPTION OF DRAWINGS

FIG. 1 shows a schematic cross section of a part of a semiconductor structure comprising a photodiode;

FIG. 2 shows a schematic cross section of a part of a photodiode;

FIG. 3 shows a graph of a doping profile of a photodiode;

FIG. 4A to 4F show a sequence of schematic diagrams illustrating a method of forming a photodiode;

FIG. 5 shows a schematic top view of a semiconductor structure comprising a photodiode;

FIG. 6 shows a flow diagram illustrating the steps of a method of forming a photodiode;

FIG. 7 illustrates a further semiconductor structure comprising a primary photodiode and a reference photodiode;

FIG. 8 shows a schematic cross section of a part of a further semiconductor structure comprising the reference photodiode of FIG. 7;

FIG. 9 shows a graph of an experimentally obtained spectral response of a photodiode;

FIG. 10 shows a table of experimentally obtained spectral response values of a photodiode;

FIG. 11 shows a schematic cross section of an optical sensor;

FIGS. 12A to 12E show schematic cross sections of a semiconductor structure in subsequent steps of making an optical sensor;

FIG. 13 shows a graph of the spectral response; and

FIG. 14 shows a schematic cross section of an optical sensor.

### DETAILED DESCRIPTION

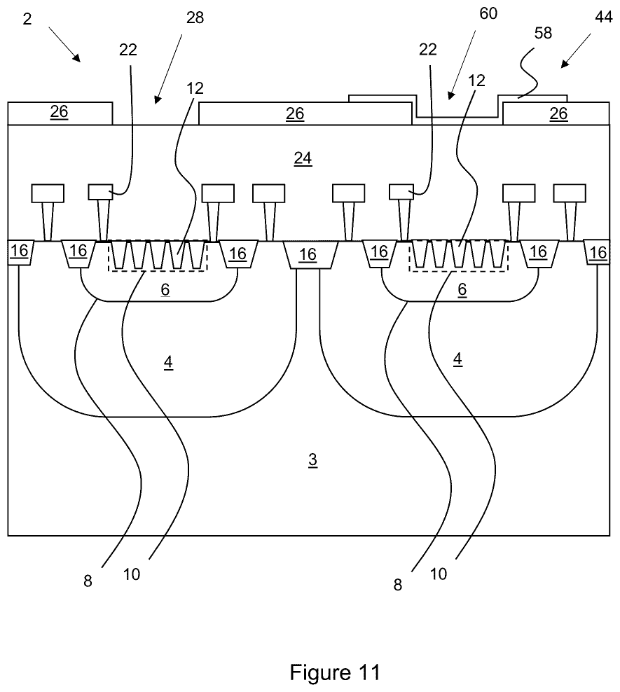

We describe a number of embodiments for the sake of completeness. However, to assist the reader of this specification we note that the claims of this application as filed relate most closely to the embodiments of FIG. 11 onwards.

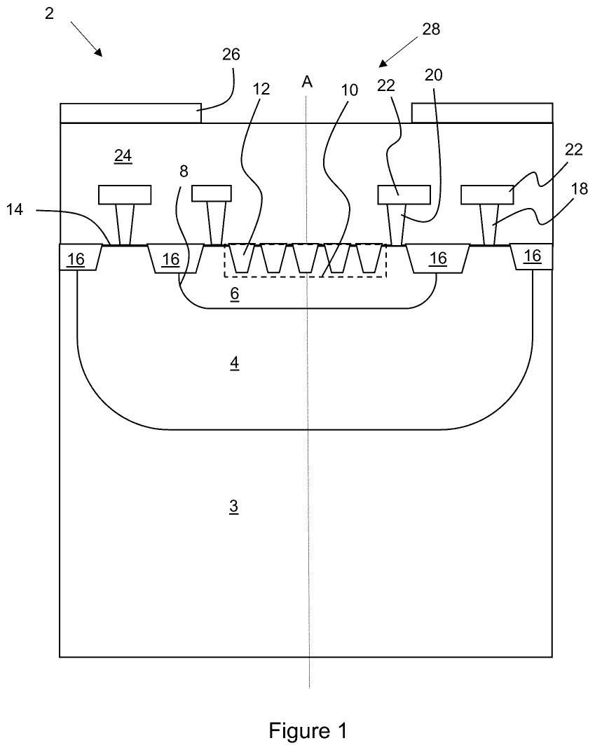

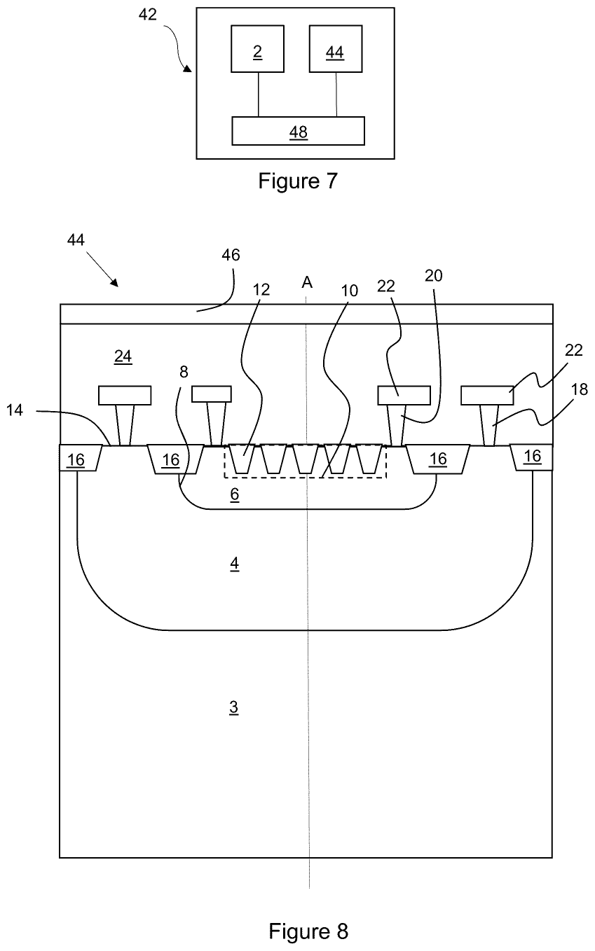

In overview, with reference to FIGS. 1 to 6, a method of forming a photodiode is described. The photodiode of FIGS. 1 to 6 is formed using a specific sequence of doping steps together with steps of forming an effective medium, which can reduce the chance of trapped charge carriers and thereby increase the sensitivity to UV light. Further, an embodiment of an optical sensor suitable for detecting low levels of light having a wavelength in a range of 200 to 275 nm is described with reference to FIGS. 7 to 10. As described in detail below, the optical sensor comprises a primary photodiode (e.g. the photodiode of FIGS. 1 to 6) as well as a reference photodiode (which has a similar sensitivity as the primary photodiode to light in a range of 275 to 1100 nm but which is essentially insensitive to light in a range of 200 to 275 nm). When in use, the current of the reference photodiode can be subtracted from the current of the primary photodiode to accurately determine the intensity of the incident light in the range of 200 to 275 nm.

Referring to FIGS. 1 to 6, a method of forming a photodiode using a specific sequence of doping steps together with the steps of forming an effective medium, which can reduce the chance of trapped charge carriers and thereby increase the sensitivity to UV light. In particular, the method comprises doping the sides and bottom of the trenches formed in the light sensitive area with two injection steps at different angles. A high doping concentration along the interface that steadily decreases towards the pn-junction pushes generated charge carriers away from the interface and towards the pn-junction (for detection).

FIG. 1 shows a photodiode 2 for UV detection. The photodiode 2 comprises a silicon wafer 3 comprising a first, n-doped, well 4 connected to the cathode of the photodiode 2, and a second, p-doped, well 6 connected to the anode of the photodiode 2. A pn-junction 8 is formed between the first well 4 and the second well 6. A patterned layer 10 being an effective medium comprising trenches 12 filled with oxide is located at the surface 14 of the silicon wafer 3 in the second well 6 in order to reduce reflection losses at the interface. The trenches 12 may be round or hexagonal holes arranged in an array to cover the light sensitive area associated with the pn-junction 8. The different well regions 4 and 6 are separated along the surface 14 by STI 16. A cathode contact 18 is connected to the first well 4, and an anode contact 20 is connected to the second well 6. Both contacts 18 and 20 are connected to a first metal layer 22 of a backend stack 24 of the photodiode 2. The backend stack 24 also comprises a passivation layer 26, with a UV window 28 overlapping the light sensitive area of the photodiode. Carriers generated by light absorbed in the p-doped well 6 are pushed by the inherent electric field due to the continuously falling doping profile towards the pn-junction 8. In particular, the doping concentration in the silicon at the interface between the trenches 12 and the silicon in the second well 6 is increased and continuously decreasing away from the interface, thereby reducing the risk of charge carriers being influenced at the interface. This influence can be due to changes in the electric field. For example, if the dielectric layers on top of the silicon change their trapped charge level.

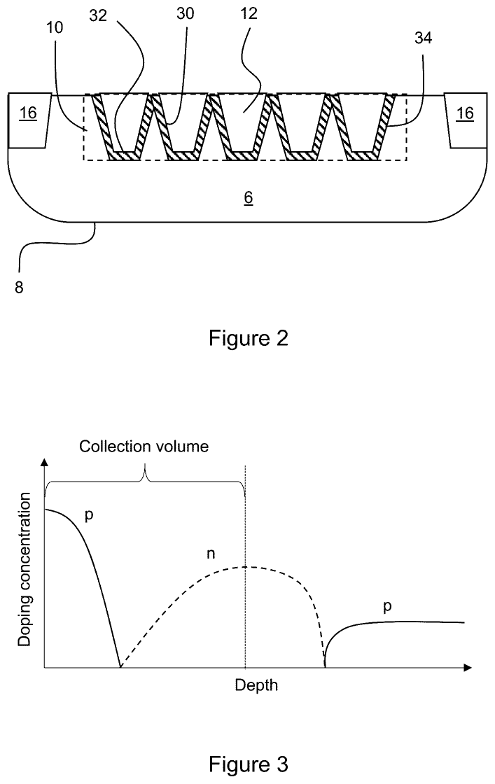

FIG. 2 shows an enlarged diagram of the second well 6 of the photodiode 2 shown in FIG. 1. The second well 6 comprises the patterned layer 10 comprising trenches 12 filled with oxide forming an effective medium with a refractive index between that of silicon and silicon oxide. Each trench 12 comprises sides 30 and a bottom 32. A layer 34 with increased doping concentration (relative to the rest of the well 6) runs along the interface (i.e. along the sides 30 and bottom 32 of the trenches 12) between the oxide in the trenches 12 and the silicon in the well 6. The layer with increased doping can reduce the risk of charge carriers generated close to the interface from becoming trapped.

FIG. 3 is schematic graph of the doping profile of the photodiode, with the doping concentration plotted against the depth along the line A shown in FIG. 1. The depth starts at the bottom of the trench 12 and runs into the epitaxial silicon of the wafer 3. The doping concertation falls continuously with depth in the p-doped well 6 towards the pn-junction 8. Charge carriers generated in this region will be pushed by the intrinsic electric field towards the pn-junction 8. The doping concentration decreases continuously from a peak concentration in the p-doped region towards the pn-junction, defining a collection volume, within which generated charge carriers are pushed to the pn-junction by the intrinsic electric field.

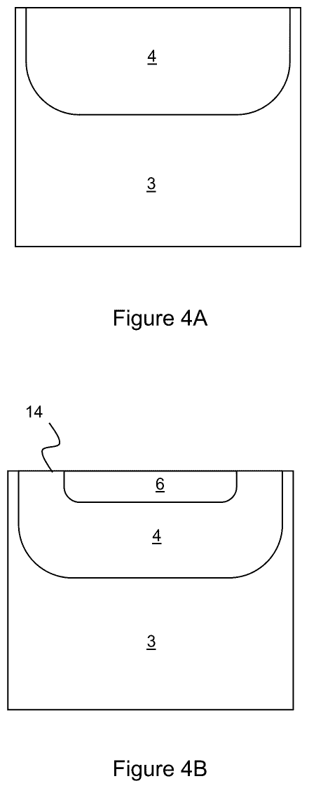

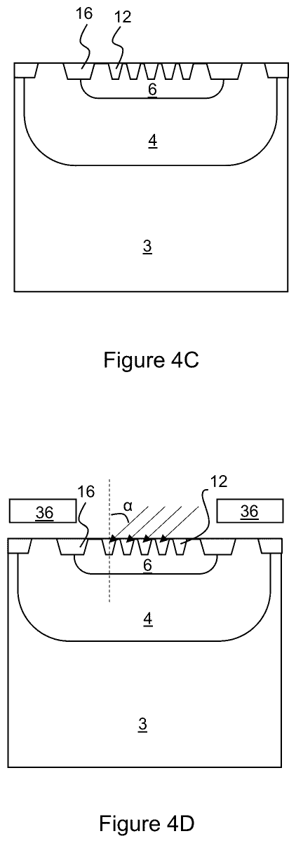

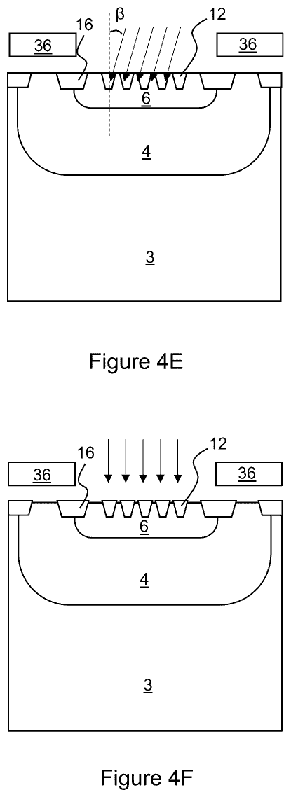

FIGS. 4A to 4F show a sequence of steps of a method of forming a photodiode.

FIG. 4A shows the wafer 3 with a first well 4 formed. The first well 4 is formed by injecting phosphorus (P) as dopant with an injection energy of 2 MeV to 3 MeV and so as to create a peak concentration in the range of 1e15 cm⁻³ to 1e19 cm⁻³.

FIG. 4B shows the wafer 3 after forming the second well 6 at the surface 14 of the wafer 3 before STI. The second well 6 is formed by injecting boron (B) with an injection energy of 10 keV to 20 keV and so as to create a peak concentration in the range of 1e14 cm⁻³ to 1e18 cm⁻³.

FIG. 4C shows the wafer 3 after forming trenches 12 and 16 in the surface 14 of the wafer 3 before filling with oxide. The trenches 16 for isolation and the (smaller) trenches 12 for forming an effective medium are formed using STI technology.

FIG. 4D shows a step of doping wherein BF2 dopants are injected at an angle α and with an injection energy of 20 keV and 30 keV using a mask 36. The doping step is performed after the STI liner oxide anneal (to form a thin layer of silicon oxide in the trenches 12), and before the STI oxide fill (deposition). The angle α of injection is in the range of 30° to 45° so as to dope the sides of the trenches 12. The wafer or injection source is rotated about a normal to the surface 14 and the injection repeated from at least four different directions, to provide uniform doping of the sides around the trenches 12. The injection angle α relative to the normal remains the same for each injection of the doping step.

FIG. 4E shows another step of doping wherein BF2 dopants are injected at another angle β, which is less than the injection angle α of the previous doping step. The doping step is performed before the STI oxide fill (deposition). The doping is performed with an injection energy in the range of 10 keV to 25 keV and is in general less than the injection energy of the previous doping step described in association with FIG. 4D above. The same mask 36 is used in this doping step, as it is the same region of the wafer 3 that is being doped. The injection angle β is in the range of 1° to 10° in order to dope the bottom of the trenches 12. The wafer 3 or injection source is rotated about a normal to the surface 14 and the injection repeated from at least four different directions, to provide uniform doping of the bottom of the trenches 12. The injection angle β relative to the normal remains the same for each injection of the doping step. In an alternative embodiment, the injection angle β is set to 0°, in which case the wafer and source do not need to be rotated to achieve uniform doping.

FIG. 4F shows a further step of doping after filling the STI trenches 12, 16. The further step of doping increases the doping concentration at the surface of the semiconductor wafer between the trenches 12.

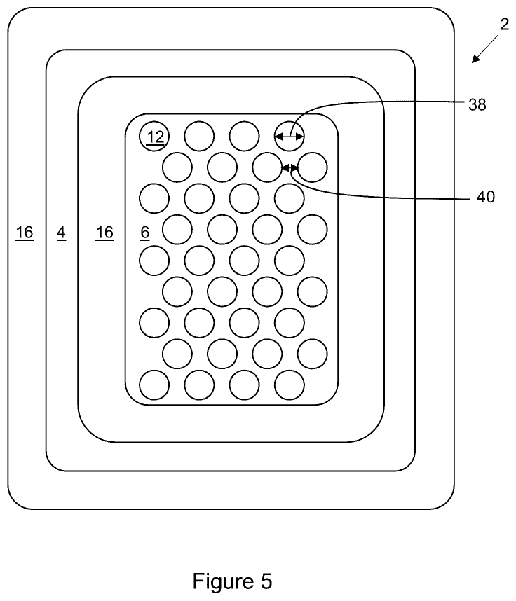

FIG. 5 shows a schematic top view of a part of a photodiode 2. The photodiode 2 comprises an array of trenches 12 being circular holes at the centre arranged to receive incident light. The holes have width 38 in the range of 220 nm to 350 nm and a spacing 40 between adjacent holes in the range of 70 nm to 210 nm. In general the spacing between the trenches 12 is smaller than the width of the trenches 12. The central (anode) area, corresponding to the underlying p-doped well 6, is surrounded by isolation 16. Outside the isolation 16 is a ring (cathode) area, corresponding to the n-doped well 4, which is in turn surrounded by outer isolation 16. The photodiode may comprise a further outer p-doped anode ring and an n-doped guard ring (not shown).

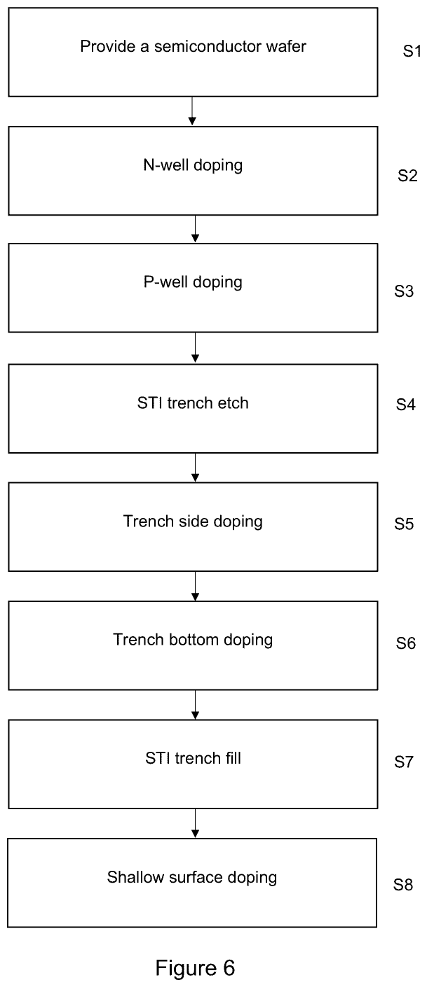

FIG. 6 shows a flow diagram of a method of forming a photodiode. The method comprises providing a semiconductor wafer (step S1). The wafer is a silicon wafer comprising a bulk silicon substrate and a doped epitaxial layer. A first doping step is performed to form an N-well in the epitaxial layer (step S2). After forming the N-well, a second step of doping is performed to form a P-well at the surface of the wafer and thereby form a pn-junction between the P-well and the N-well (step S3). After forming the pn-junction, an STI trench etch is performed to form a plurality of trenches in the P-well in the surface of the wafer (step S4). Before filling the trenches, a third doping step is performed at a relatively high angle with respect to a normal to the surface of the wafer to dope the sides of the trenches (step S5). A fourth doping step at a lesser angle is performed to dope the bottom of the trenches (step S6). After the fourth step of doping, the trenches are filled by oxide deposition (step S7). After filling the trenches, a fifth step of doping is performed to increase the doping in the p-doped well along the surface of the wafer (step S8). The method may comprise further steps as part of a backend of line (BEOL) process for forming anode and cathode contacts in order to apply a voltage across the pn-junction.

In general, the present disclosure provides a method of forming a photodiode. The method may be part of the manufacturing process of a photodetector or imaging device comprising one or more such photodiodes. The method is typically part of a complementary metal oxide semiconductor (CMOS) process, comprising a front end of line (FEOL) process for forming active semiconductor devices such as photodiodes and transistors, and a back end of line (BEOL) process for forming metal layers and contacts to the active semiconductor devices. The method comprises providing a semiconductor wafer, performing a first doping to form a first well in the wafer having a first type of doping, and performing a second doping to form a second well having a second type of doping, so as to form a pn-junction of the photodiode between the first well and the second well. The second step of doping may create a shallow p-well (or n-well) in a top layer of the wafer, which may be referred to as the active layer or diffusion layer and is typically a lightly doped epitaxial layer of silicon. The method further comprises performing a shallow trench isolation (STI) etch to form a plurality of trenches in the surface of the wafer in the second well.

High energy light (e.g. UV light) can change the charge in layers, which in turn can change the electrical field acting in the silicon. This effect causes degradation of photodiode performance from exposure to such light. The described method can provide a photodiode with a strong doping related field, which can lower or completely compensate this effect from UV exposure.

The method comprises performing a third doping by injecting dopants at a first angle relative to the surface of the wafer in order to increase a doping concentration of the second type of doping at along the sides of the trenches in the second well, and performing a fourth doping by injecting dopants at a second angle relative to the surface of the wafer in order to increase a doping concentration of the second type of doping at the bottom of the trenches in the second well. The third and fourth doping are performed after etching the trenches in the semiconductor wafer but before filling the trenches with STI material to provide a more even doping along the interface of the trenches. The method further comprises performing a fifth doping to increase a doping concentration of the second type of doping at the surface of the semiconductor wafer between the trenches in the second well, and forming a first contact for contacting the first well and forming a second contact for contacting the second well in order to apply a voltage across the pn-junction when in use. The contact formation may be part of a CMOS BEOL process further comprising forming a backend stack comprising a plurality of metal layers separated by interdielectric layers.

The first angle may be in the range of 30° to 45° with respect to a normal to the surface. This relatively high angle can allow the dopants to be efficiently injected into the sides (also referred to as sidewalls) of the trenches. The STI etch typically creates trenches (e.g. holes) having sloped sidewalls. The second angle may be in the range of 0° to 15° with respect to a normal to the surface. This relatively small angle is used to dope the substantially flat bottom of the trenches. The first, second and fifth doping may also be performed by injecting dopants having an injection angle in the range of 0° to 15° to the normal (where 0° means injection perpendicular to the surface of the semiconductor wafer). At least the third doping and preferably all doping steps can be performed at four or more different rotation angles about a normal to the surface of the wafer. This can provide a more uniform doping in three dimensions when the injection angle is >0°. In some embodiment, six different (preferably equidistant) rotation angles are used (e.g. at 0°, 60°, 120°, 180°, 240°, 300°).

The third doping may comprise injecting the dopants with a first injection energy, while the fourth doping comprises injecting the dopants with a second injection energy, and wherein the first injection energy is greater than the second injection energy. For example, the first injection energy may be in the range of 20 keV to 30 keV, and the second injection energy may be in the range of 10 keV to 25 keV. The dopants for the third and fourth doping may be BF2 molecules.

The first doping may comprise injecting dopants with an injection energy in the range of 2 MeV to 3 MeV. The dopants may be P atoms. The second doping may comprise injecting dopants with an injection energy in the range of 10 keV to 20 keV. The dopants may be B atoms. The fifth doping may comprise injecting dopants with an injection energy in the range of 10 keV to 20 keV. The dopants may be B atoms.

The second, third, fourth and fifth doping steps can be performed using the same mask. The second, third, fourth and fifth doping steps are performed so as to create a continuously falling doping concentration from the trenches to the pn-junction. This can reduce the risk of charge carriers getting trapped or otherwise not reaching the pn-junction for detection.

The semiconductor wafer is typically a silicon wafer comprising an epitaxial layer within which the first well and the second well are formed. In other embodiments, the wafer may be a SOI wafer comprising an epitaxial silicon layer on a buried oxide layer.

The method may further comprise forming a backend stack comprising a plurality of metal layers separated by interdielectric layers, and a nitride passivation layer, and locally removing the nitride passivation layer in a region overlapping the pn-junction (to create a so called UV window).

The trenches may comprise circular or hexagonal holes having a width in the range of 220 nm to 350 nm and a spacing from an adjacent hole in the range of 70 nm to 210 nm. In an alternative embodiment, the trenches may define raised portions (e.g. pillars or spikes) of semiconductor material left in the light sensitive region. The method may further comprise filling the trenches with silicon oxide to form a layer of an effective medium at the surface of the wafer, wherein the effective medium has a wavelength dependent refractive index n between the refractive index of silicon oxide and silicon. An optimal refractive index of the effective medium can be calculated by

$${n}_{1} = \sqrt{{n}_{0} \cdot {n}_{2}} ,$$

Wherein n0 and n2 are the refractive indices of the two materials on either side of the effective medium (in this case silicon oxide and silicon respectively). Using the second material (silicon) in forming the effective medium as described herein can be particularly advantageous for forming an effective anti-reflective coating (ARC) layer, as the refractive index of the effective medium will change substantially along with that of the second material. That is the effective medium can have similar wavelength dependence to that of the underlying material.

Also described herein is a semiconductor structure comprising a photodiode formed according to the method described above, and a sensor comprising a plurality of such photodiodes.

A particular advantage of the photodiode may be the increased sensitivity in the UVC range (about 100 nm to 280 nm wavelength) against state-of-the-art CMOS integrated devices and high performance discrete devices. Accordingly, an advantage is the ability to detect weaker signals or to save chip area as the active sensor area can be half as large for the same response and results in half capacitance. The smaller area can also provide a smaller dark current. Another advantage can be that less light is reflected and the collection volume of the device is smaller, so it is less receptive to noise and potentially faster, it may also have a higher linearity range, as the internal resistance is smaller for a similar photocurrent compared to conventional devices.

Embodiments have shown an increased reliability of the response of photodiodes against UV light stress. While most silicon based UV detectors suffer strong degradation from UV light exposure, photodiodes formed according to the described method have shown a significant decrease in such degradation. Hence, the photodiodes can perform well under UV light with little to no measurable degradation.

Generally, silicon based photodiodes may be less sensitive to light in the UVC range (100 to 280 nm) than to light in the UVB (280 to 315 nm), UVA (315 to 400 nm) and the visible range (400 to 800 nm). This can be problematic in low light applications, where the low intensity of the signal of interest results in a small photocurrent and thereby a small output signal of the photodiode. In this case, it can be difficult to determine the signal of interest accurately (e.g. to distinguish the signal of interest from noise in the output signal) for two reasons. Firstly, even small amounts of stray light in the UVA, UVB or visible range can contribute to a large noise level in the output signal (due to the higher sensitivity of the photodiode in this spectral range). Secondly, noise caused by the (temperature-dependent) dark current of the photodiode (i.e. the leakage current that flows when a bias voltage is applied to the photodiode) can further obscure the signal (i.e. the current produced by the incident light of interest).

It is known that the noise level of the output signal of the photodiode can be improved by subtracting the current of a dark reference device from the current of the photodiode. The dark reference device is typically a similar photodiode (thus providing a dark current with a similar temperature dependency as the primary photodiode) which is insensitive to light. Thus, the dark reference device can be identical to the primary photodiode but provided with a light shield (e.g. a metal layer) to prevent light from reaching the optical sensitive area. For light sensing applications in the UVA and UVB range (280 to 400 nm), the optical sensitive area of the reference device may be covered with a thin layer (typically between 100 and 400 nm thick) of polysilicon (as part of the CMOS manufacturing process) instead of a metal layer. This has the effect that the reference photodiode is no longer “dark” (i.e. shielded from all light) but detects the unwanted stray light in visible and near-infrared part of the optical spectrum (i.e. light with wavelengths larger than 400 nm). This is because the relatively thin polysilicon layer exhibits typically moderate optical absorption for light in the visible and near-infrared range (e.g. 400 to 1100 nm), and strong optical absorption for UV light (i.e. a polysilicon layer can be transparent or translucent visible and near-infrared light, and essentially opaque for UV light). Thus, subtracting the current of the reference diode from the current of the primary photodiode corrects the output signal not only for the dark current but also for the photocurrent caused by visible and near-infrared stray light, thereby improving the UV-light detection accuracy.

However, the above described approach may be insufficient when the signal of interest is in the UVC range (100 to 280 nm). This is because the above described approach does not correct for stray light in the UVA and UVB range (280 to 400 nm), since the polysilicon layer shields the (optical sensitive area of the) reference diode from UVA and UVB light. Thus, it is desirable to provide an optical sensor which overcomes these problems of conventional optical sensors and enables the detection of low intensity signals in the UVC range of the optical spectrum. Such an optical sensor is described with reference to FIGS. 7 to 10.

In general, embodiments described herein provide an optical sensor comprising a “primary” and a “reference” photodiode. The primary photodiode and the reference photodiode are substantially identical except that the reference photodiode comprises a light shield covering its optical sensitive area. In particular, the light shield of the reference photodiode is configured to be substantially transparent to UVA, UVB, visible and near-infrared light, and to prevent (or substantially attenuate) UVC light from entering the optical active area (i.e. to prevent any light induced charge carriers). In particular, the light shield of the reference photodiode may be implemented as a wavelength-selective absorption layer configured to exhibit low optical absorption in a wavelength range of 300 to 1100 nm, and high optical absorption in a wavelength range of 200 to 275 nm. As described in detail below, this light shield may conveniently be implemented by a silicon nitride passivation layer.

In the embodiment shown in FIG. 7, an optical sensor 42 comprises, as a primary photodiode, the photodiode 2 as described above with reference to FIGS. 1 to 6, and a reference photodiode 44. The optical sensor 42 is configured to determine a light level of incident light based on a difference between the electrical current generated by the reference photodiode 44 and the electrical current generated by the primary photodiode 2. To this end, the optical sensor 42 may further comprise circuitry 48 connected to the photodiodes 2, 44, and configured to determine a difference between the currents generated by the photodiode 2, 44 (e.g. by subtracting the current generated by the reference photodiode 44 from the current generated by the primary photodiode 2) and to provide an output signal based on the determined difference. Any known suitable design may be used to implement the circuitry 48. As described in detail below, the optical sensor 42 may be particularly well suited for sensing UVC light, and in particular light in a wavelength range of 200 to 275 nm.

In general, the optical sensor 42 is a CMOS integrated circuit device. The primary and the reference photodiode 2, 44 may be formed on the same semiconductor wafer. Typically, the primary and the reference photodiode 2, 44 are formed close to each other (e.g. directly adjacent), such that both photodiodes experience substantially the same (amount of) stray light and operate at substantially the same temperature. This may have the effect that noise caused dark currents and stray light can be efficiently corrected. Whilst the embodiment of FIG. 7 includes only one primary and one reference photodiode 2, 44, it is understood that other embodiments may comprise a plurality of primary photodiodes and a (corresponding) plurality of reference photodiodes. In this case, the photodiodes may be arranged in a regular array (e.g. in a one or two-dimensional array) such that instances of primary and reference photodiodes alternate.

FIG. 8 shows a schematic cross section of the reference photodiode 44. The reference photodiode 44 is a variation on the photodiode 2 of FIG. 1, and to avoid unnecessary repetition, like reference numerals will be used to denote like features. Like the primary photodiode 2 of FIG. 1, the reference photodiode 44 of FIG. 8 comprises a backend stack 24 which comprises a passivation layer 46. However, in contrast to the primary photodiode 2, the backend stack 24 of the reference photodiode 44 does not comprise the UV window 28. Instead, the passivation layer 46 of the backend stack 24 of the reference photodiode 44 overlaps the light sensitive area of the photodiode. Thus, the passivation layer 46 may be a featureless layer covering the entire backend of the reference photodiode 44. The passivation layer 46 of the reference photodiode 44 may comprise silicon nitride (e.g. the passivation layer 46 may be made of silicon nitride).

In the embodiment of FIG. 8, the silicon nitride comprising passivation layer 46 acts as the aforementioned light shield of the reference photodiode 44. Thus, firstly, the passivation layer 46 shields the light sensitive area of the reference photodiode 44 from incident UVC light since silicon nitride exhibits strong optical absorption for UVC light, i.e. incident UVC light is blocked (or at least substantially attenuated) by the passivation layer 46. Secondly, the passivation layer 46 is substantially transparent for light in the range of 300 to 1100 nm (i.e. UVA, UVB, visible and near-infrared light), thereby allowing such light to enter the light sensitive area of the reference photodiode 44 and create light induced charge carriers.

The reference photodiode 44 may be formed according to the method of forming the primary photodiode 2 described above, except that no step of removing the nitride passivation layer for forming the UV window 28 is required. Thus, a particular advantage of the reference photodiode 44 of FIG. 8 may be that the reference photodiode 44 can be fabricated using CMOS processes and without requiring additional steps compared to the primary photodiode 2 (the reference photodiode may need fewer fabrication steps since the UV window 28 is not formed). This makes it possible to form the optical sensor 42 in a cost effective manner.

It is understood that in embodiments where the primary photodiode 2 and the reference photodiode 44 are formed on the same semiconductor wafer (e.g. adjacent to each other), the passivation layer 26 of the primary photodiode 2 and the passivation layer 46 of the reference photodiode 44 may be formed in the same process step (i.e. as a single layer), and may be formed as an outermost encapsulating protective layer of the optical sensor.

In general, the material and the thickness of the layer 46 may be selected such that an optical transmission of the layer 46 is less than 70% in a wavelength range of 200 to 275 nm. Additionally or alternatively, the material and the thickness of the layer 46 may be selected such that the optical transmission of the layer 46 is greater than 70% in a wavelength range of 300 to 1100 nm. For example, in an embodiment where the passivation layer 46 of the reference photodiode 44 is made of silicon nitride, the thickness of the passivation layer 46 may be in the range of 300 to 1000 nm.

Experimentally, it has been found that embodiments of the reference diode 44 exhibit a dark current which is approximately 40% lower than the dark current of the primary photodiode 2. This has the effect that, in the absence of any incident light, subtracting the current of the reference diode 44 from the current of the primary diode 2 results in a positive current. This is beneficial compared to the case where the reference photodiode exhibits the same average dark current as the primary photodiode because the read out circuitry may fail when the direction of the subtracted current (randomly) changes (because the dark current of the reference photodiode is sometimes larger and sometimes smaller than the dark current of the primary photodiode). Further, it has been found that the responsivity of the reference photodiode 44 is approximately 10% lower across a spectral range of 200 nm to 1100 nm than the responsivity of the primary photodiode 2, thus also in the presence of light, negative currents are generally prevented.

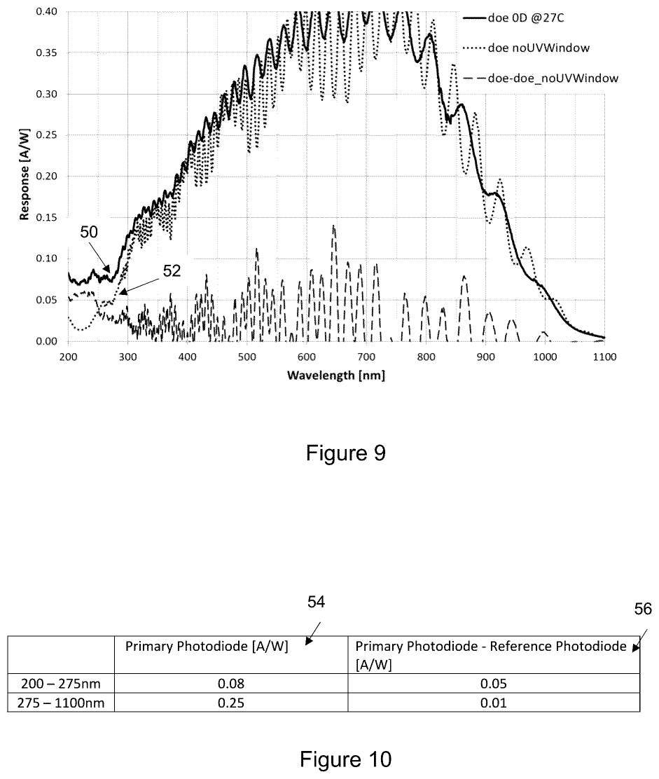

Further experimentally obtained data is described with reference to FIGS. 9 and 10. FIG. 9 shows a graph illustrating the respective responsivities 50, 52 of the primary photodiode 2 and the reference photodiode 44 over a spectral range of 200 nm to 1100 nm. As shown in FIG. 9, the responsivity 50 of the primary photodiode 2 is substantially higher than the responsivity 52 of the reference photodiode 44 in a range of 200 to 275 nm (because the nitride passivation layer 46 absorbs strongly in this range). The responsivities 50, 52 are however substantially equal over a range of 275 to 1100 nm (the average responsivity of the reference photodiode may be 10% lower). Thus, because both photodiodes have substantially the same responsivity over the range of 275 to 1100 nm, subtracting the respective currents removes the contributions of any stray light in this spectral range from the output signal of the optical sensor 42. It is understood that the benefits of accurately removing the stray light contributions often outweigh drawbacks caused by a small, residual sensitivity of the reference photodiode 44 to light in the target range (i.e. 200 to 275 nm). In other words, a small but noise-free signal is typically acceptable (i.e. such a signal may have a better signal to noise ratio than a larger signal on top of a large noise level).

FIG. 10 shows a table with experimentally obtained values. Column 54 shows the average responsivities of the primary photodiode 2 respectively over the spectral ranges of 200 to 275 nm and 275 to 1100 nm. Column 56 shows the corresponding responsivities when the responsivity of the reference photodiode 44 is subtracted from the responsivity of the primary photodiode 2 (thus the values of column 56 correspond to the effective responsivity of the optical sensor 42). Thus, by the subtracting the currents of the two photodiodes 2, 44, the responsivity of the optical sensor 42 is reduced from 0.25 A/W to 0.01 A/W for the (stray) light range of 275 to 1100 nm. In other words, the output of the optical sensor 42 is substantially insensitive to light in this range. The optical sensor 42 is however sensitive to light in the (target) range of 200 to 275 nm where the average responsivity of the optical sensor 42 is reduced from 0.08 A/W to 0.05 A/W by subtracting the currents of the photodiodes 2, 44 (this reduction is due to the dark current cancelation and the residual sensitivity of the reference photodiode 44 to light in the target range). Thus, the optical sensor 42 is sensitive to light in the UVC range while being substantially insensitive to stray light (in the UVB, UVA, visible and near-infrared range) and to temperature variations (because both photodiodes 2, 44 have dark currents with the same temperature dependency). The optical sensor 42 mitigates therefore the need for costly and bulky optical filters to reduce the noise level caused by stray light.

FIG. 11 shows a schematic cross section of another embodiment of an optical sensor 42 comprising a first (primary) photodiode 2 and a second (reference) photodiode 44. The optical sensor 42 may be the optical sensor 42 described with reference to FIG. 7 above. The first photodiode 2 may be the photodiode illustrated in FIG. 1 and common elements are therefore not described again. The second photodiode 44 is substantially identical to the first photodiode 2 apart from an absorption layer 58 located in the opening 60 over the light sensitive region associated with the pn-junction 8 of the second photodiode 44. The absorption layer may be a silicon nitride absorption layer.

An advantage of these embodiments with a thin absorption layer, is an improved signal to noise ratio due to a better match of the spectral response functions between the sensing and the reference device. Accordingly, an advantage may be higher sensitivity or less chip area needed to achieve equal sensitivity, or simpler and cheaper external filters to achieve the same sensing performance in the UV range. These embodiments can also provide less incidence angle dependency of the reference subtraction method, as the oscillation shift of a thin layer is smaller. The oscillation in the spectrum is slow (less than one minima-maxima across the full spectrum).

The optical sensor 42 may comprise a larger number of photodiodes of which two are illustrated for simplicity. In particular, the sensor 42 may comprise an array of photodiodes. A subset of the photodiodes are reference photodiodes such as the second photodiode 44 comprising an absorption layer 58. In one embodiment, each primary photodiode has a corresponding reference photodiode. In other embodiments, the number of primary photodiodes may be greater than the number of reference photodiodes. For example, two or more primary photodiodes may be associated with the same reference photodiode 44. The output signal from the reference photodiode 44 can then be subtracted from the output signal of each primary photodiode with which it is associated.

In general, the optical sensor 42 is configured to combine the signals produced by the first/primary photodiode 2 and the second/reference photodiode 44 to output a signal representing the difference between the light incident on the first/primary photodiode 2 and the light reaching the second/reference photodiode 44 after passing through said absorption layer 58.

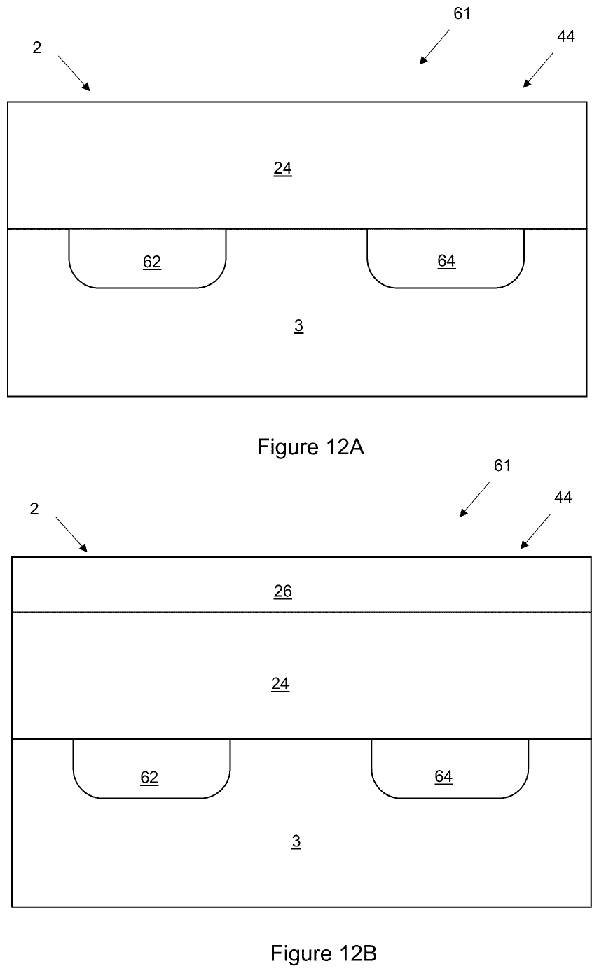

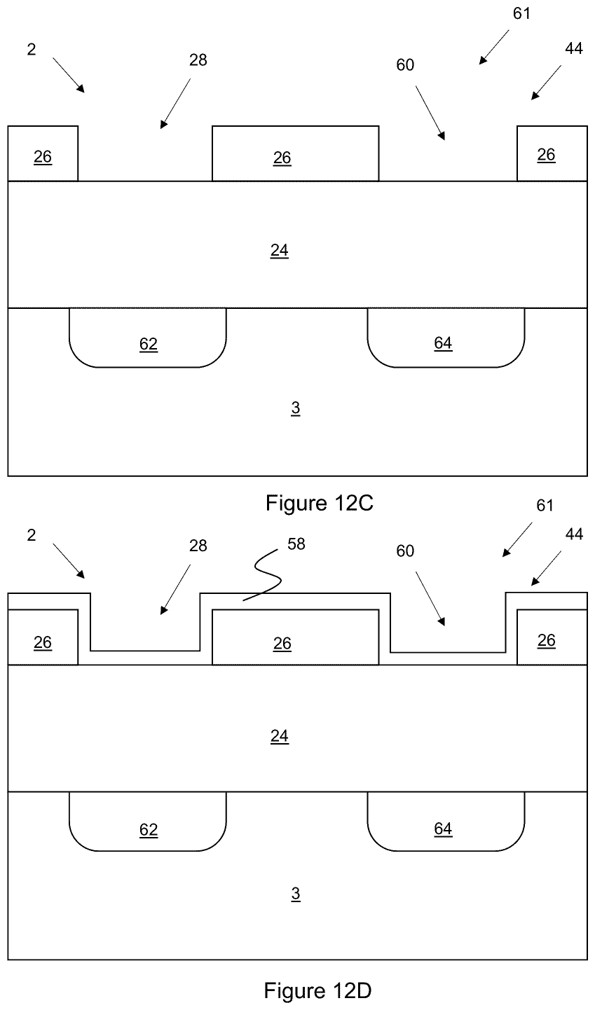

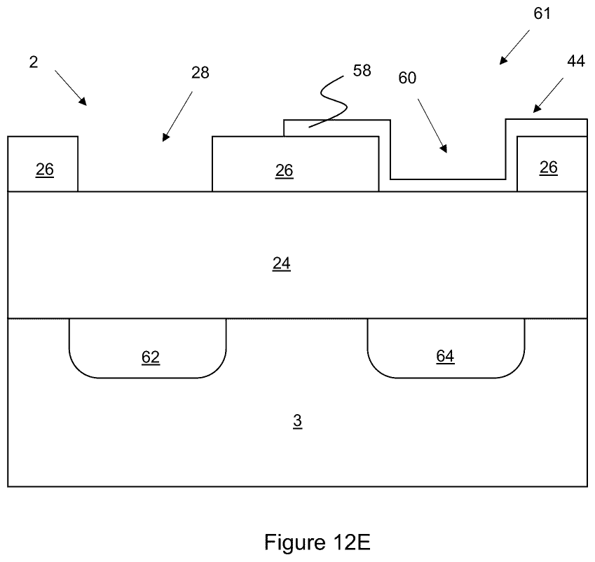

The reference photodiode 44 may be formed according to the method of forming the primary photodiode 2 described above, with additional steps for providing the absorption layer 58 in the opening 60. The steps of a method of forming the absorption layer 58 are illustrated in FIGS. 12A to 12E.

FIG. 12A to 12E show schematic cross sections of a semiconductor structure in subsequent steps of making an optical sensor 42, such as the optical sensor 42 described in relation to FIG. 11 above.

FIG. 12A shows the semiconductor structure 61 comprising a silicon wafer 3 (also referred to as a silicon layer) with light sensitive regions 62 and 64 of the primary photodiode 2 and the reference photodiode 44 respectively. The light sensitive regions 62 and 64 are formed by respective pn-junctions between doped regions (not shown) in the silicon wafer 3. Over the silicon wafer 3, a backend stack 24 is located. The backend stack 24 typically comprises metal layers, interdielectric layers and vias connecting parts of different metal layers (not shown). The metal layers provide connections to the doped regions in the silicon wafer 3 in order to provide input and output signals from the photodiodes 2, 44.

FIG. 12B shows the semiconductor structure 61 after providing a passivation layer 26. The passivation layer 26 may comprise a nitride layer. The nitride layer may be deposited at a rate of about 900 nm/min to form a passivation layer having a thickness of about 600 nm. For example, the nitride layer may be deposited using an RF power of about 900 W.

FIG. 12C shows the semiconductor structure 61 after opening the passivation layer 26 to provide a first opening 28 over the light sensitive region 62 of the primary photodiode 2 and a second opening 60 over the light sensitive region 64 of the reference photodiode 44. The openings 28, 60 may be referred to as UV windows, as they allow UV light to reach the light sensitive regions 62, 64. The passivation layer 26 may be patterned using a photoresist and etch.

FIG. 12D shows the semiconductor structure 61 after depositing a thin absorption layer 58 over the passivation layer 26. The absorption layer 58 is a nitride layer and may have a thickness of about 20 nm. The absorption layer 58 may be deposited at a rate of about 100 nm/min, and with a RF power of about 100 W. The absorption layer 58 covers the first and second openings 28, 60 in the passivation layer 26.

FIG. 12E shows the semiconductor structure 61, comprised by the optical sensor 42, after selectively removing the absorption layer 58 from the primary photodiode 2. A remaining part of the absorption layer 58 is located in the second opening 60 over the light sensitive region 64 of the reference photodiode 44. The absorption layer 58 may be selectively removed using a photoresist and etch.

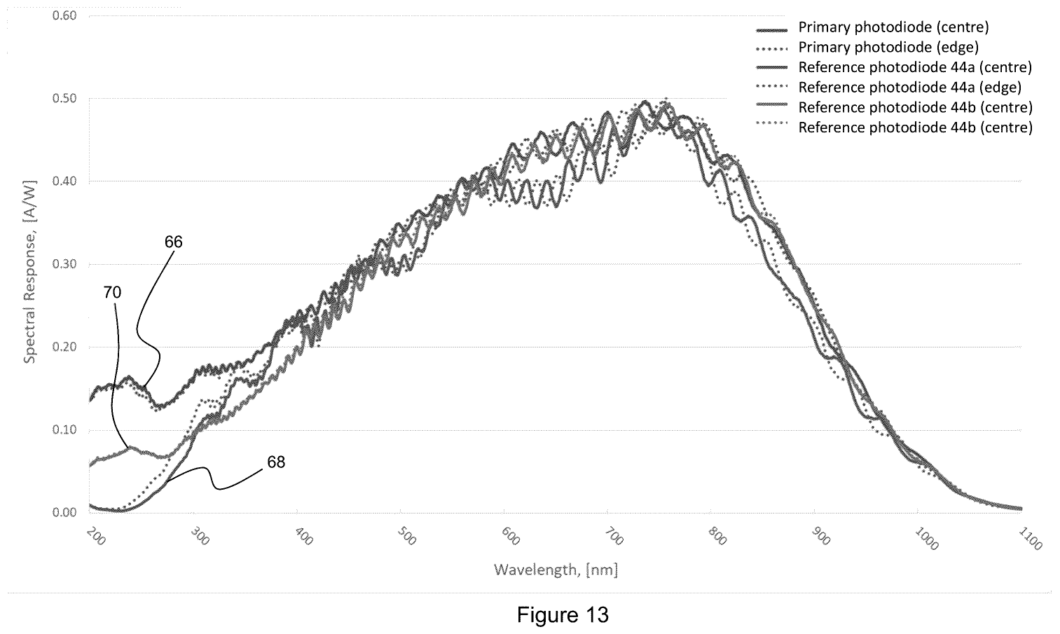

FIG. 13 shows a graph of the spectral response of different photodiodes, plotted as output current per power of incident light (Amps per Watt) as a function of wavelength (nm). The different photodiodes comprise a primary (sensing) photodiode, a reference photodiode 44a with a passivation layer as a light shield, such as the photodiode described with reference to FIG. 8, and a reference photodiode 44b having a thin silicon nitride absorption layer. For each type of photodiode, the response is recorded at the centre of a wafer and at the edge of the wafer (as there is typically some variance across the wafer). The spectral response from the primary photodiode (centre) has reference number 66, the spectral response from the first type of reference photodiode 44a (centre) has reference number 68, and the spectral response from the second type of reference photodiode 44b (centre) has reference number 70. As can be seen from the graph, the spectral response of the reference diode with the thin silicon nitride absorption layer is closer to that of the primary photodiode for wavelengths>400 nm, compared to a reference diode using the passivation layer as a light shield. The reference photodiode 44b with the thin silicon nitride absorption layer can therefore suppress the unwanted signal more efficiently, leading to a significantly improved signal to noise behaviour of the UV sensor.

In an alternative embodiment, for applications where no or very little passivation is required (e.g. single use products, or products for use in controlled environments), a thin nitride absorption layer can be used as or instead of a passivation layer. In this case, the nitride absorption layer is deposited directly on the backend stack (without a passivation layer) and patterned to open the nitride absorption layer over the primary photodiode(s), while leaving the nitride absorption layer over the reference photodiode(s). The nitride absorption layer and deposition process may be substantially identical to the layer and deposition process described with reference to FIGS. 11 and 12A to 12E above.

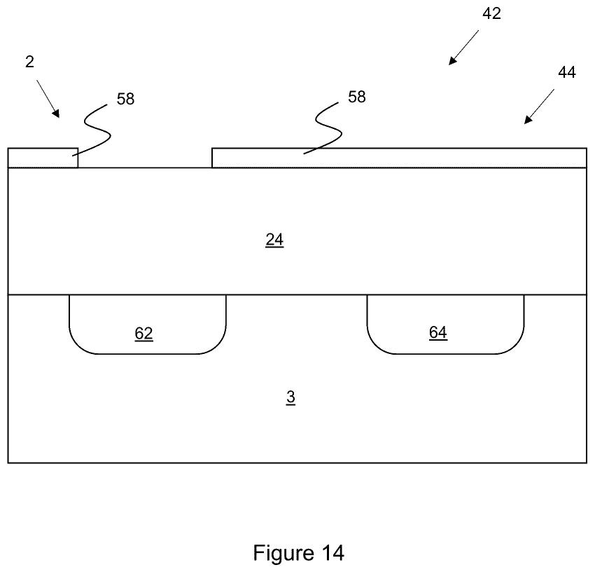

FIG. 14 shows a schematic cross section of an optical sensor 42 having a thin nitride absorption layer 58. An opening 72 is formed in the absorption layer 58 over the light sensitive region 62 of the primary photodiode 2. The absorption layer 58 overlaps the light sensitive region 64 of the reference photodiode 44. The backend stack 24 comprises metal layers and interdielectric layers (not shown), but does not comprise a nitride passivation layer. The absorption layer 58 may have a thickness<100 nm, which makes it unsuitable as a normal passivation layer, as it is too thin to provide adequate protection for most applications.

In general embodiments described herein provide an optical sensor configured to sense light in a first wavelength range in the UV spectrum, the optical sensor comprising:
a first photodiode sensitive to light in the first wavelength range and to light in a second wavelength range in the UV spectrum, wherein the second wavelength range comprises longer wavelengths than the first wavelength range, and wherein the first photodiode is configured to output a first signal in response to incident light;
a second photodiode sensitive to light in the second wavelength range and comprising an absorption layer having an optical thickness in the range of 10 nm to 250 nm to absorb light in the first wavelength range, while being substantially transparent to light in the second wavelength range, wherein the second photodiode is configured to output a second signal in response to incident light;
wherein the optical sensor is configured to combine said first and second signals to output a signal representing the difference between the light incident on the first photodiode and the light reaching the second photodiode after passing through said absorption layer. For example, the optical sensor may be configured to output the difference between the first signal and the second signal.

Preferably, the absorption layer is a silicon nitride layer (e.g. SiₓN_{y} or SiₓO_{y}N_{z}), which has suitable optical properties. Silicon nitride is relatively opaque in the UV range and relatively transparent in the visible range. However, other materials with similar optical properties may also be used as the absorption layer. For example, the absorption layer may comprise titanium oxide (TiO₂).

The absorption layer may have a thickness in the range of 5 nm to 100 nm. The absorption layer is relatively thin in order to selectively absorb UV light wavelengths in the first wavelength range whilst being substantially transparent to UV light in the second wavelength range.

The sensor typically comprises a passivation layer comprising a first opening over a light sensitive region of the first photodiode and a second opening over a light sensitive region of the second photodiode, wherein the absorption layer is located in the second opening. Hence, the second photodiode can comprise a silicon nitride layer for absorption that is separate from the normal passivation layer.

The passivation layer typically comprises a second silicon nitride layer. This is a different silicon nitride layer to that of the absorption layer when the absorption layer is a silicon nitride layer. They are formed in different steps and using different deposition parameters to provide different properties. The refractive index of the absorption layer may be different from the refractive index of the of the second silicon nitride layer of the passivation layer. The passivation layer may have a thickness greater than 200 nm. Typically, the passivation layer is much thicker than the absorption layer. For example, in an embodiment the absorption layer has a thickness of 20 nm and the passivation layer has a thickness of 600 nm.

The first wavelength range may be 200 nm to 275 nm, and the second wavelength range may be 400 nm to 1100 nm. The UV sensor may be a UVC sensor for detecting UV light with a wavelength below 300 nm. The absorption layer is then configured to selective absorb light with a wavelength below 300 nm so that the second photodiode can be used as a reference photodiode.

Embodiments described herein also provide a method of making an optical sensor configured to sense light in a first wavelength range in the UV spectrum, the method comprising:
forming a first photodiode sensitive to light in the first wavelength range and to light in a second wavelength range in the UV spectrum, wherein the second wavelength range comprises longer wavelengths than the first wavelength range, wherein the first photodiode is configured to output a first signal in response to incident light; and
forming a second photodiode sensitive to light in the second wavelength range and comprising an absorption layer having an optical thickness in the range of 10 nm to 250 nm to absorb light in the first wavelength range, and to be substantially transparent to light in the second wavelength range, wherein the second photodiode is configured to output a second signal in response to incident light;
wherein the optical sensor is configured to combine said first and second signals to output a signal representing the difference between the light incident on the first photodiode and the light reaching the second photodiode after passing through said absorption layer. For example, the optical sensor may be configured to output the difference between the first signal and the second signal.

The optical sensor formed by the method may be the optical sensor of any embodiment described above.

Preferably, the absorption layer is a silicon nitride layer (e.g. SiₓN_{y} or SiₓO_{y}N_{z}), which has suitable optical properties. Silicon nitride can be relatively opaque in the UV range and relatively transparent in the visible range. However, other materials with similar optical properties may also be used as the absorption layer. For example, the absorption layer may comprise titanium oxide (TiO₂).

The absorption layer may have a thickness in the range of 5 nm to 100 nm. For example, the thickness may be about 20 nm. The method may comprise depositing the absorption layer at a deposition rate in the range of 120 nm/min and 200 nm/min. For example, the deposition rate may be about 160 nm/min. The method may comprise depositing the absorption layer with a Radio Frequency (RF) power in the range of 80 W to 120 W. For example, the RF power may be about 100 W. The RF power relates to plasma power and the energy added to the reaction chamber for the deposition process.

The absorption layer can be provided by the reaction

SiH₄+2N₂O+He→SiₓO_{y}N_{z}+He+2H₂+N₂.

For example, the ratio of SiH₄ provided to form the absorption layer can be set to provide a pre-determined refractive index of the absorption layer. For example, the ratio can be set to provide a refractive index in the range of 1.7 to 2.2.

The method may further comprise:
forming a passivation layer over the first and second photodiodes;
etching the passivation layer to provide a first opening over a light sensitive region of the first photodiode and a second opening over a light sensitive region of the second photodiode;
depositing the absorption layer over the passivation layer and over the first and second photodiodes; and
selectively etching the absorption layer to remove the absorption layer from the first opening while leaving the absorption layer in the second opening.

For example, the material of the absorption layer (e.g. silicon nitride) can be blanket deposited over the patterned passivation layer and then removed from the first photodiode so as to form the absorption layer over the second photodiode (in the second opening of the passivation layer).

Forming the passivation layer may comprise depositing a second silicon nitride layer. Typically, the passivation layer is a single (thick) nitride layer to protect the underlying semiconductor devices and metal connections. For example, the passivation layer may be the topmost layer of a CMOS backend stack.

To form the second silicon nitride layer of the passivation layer, silicon nitride can be deposited at a rate in the range of 800 nm/min and 1000 nm/min. the method comprises depositing the silicon nitride layer with a Radio Frequency (RF) power in the range of 800 W to 1000 W. Typically, the RF power and the deposition rate of silicon nitride for the passivation layer is much greater than the RF power and deposition rate of silicon nitride for the absorption layer. This can explain the different physical properties of the passivation layer and the absorption layer even when both comprise silicon nitride. For example, the refractive index of the absorption layer can be different from the refractive index of the second silicon nitride layer of the passivation layer. The passivation layer may have a thickness greater than 200 nm. The thickness may be in the range of 200 nm to 1000 nm, for example about 600 nm.

Alternatively, the method may comprise depositing the absorption layer and selectively etching the absorption layer, without forming a passivation layer. For example, the absorption layer may be deposited directly on a top metal layer, e.g. the top metal layer of a CMOS backend stack.

The second silicon nitride layer, of the passivation layer, may be formed by the reaction:

SiH₄+NH₃+N₂→SiₓN_{y}H_{z}+by-products

The first wavelength range may comprise 200 nm to 275 nm (in the UVC range), and the second wavelength range may comprise 400 nm to 1100 nm. The second wavelength range may also comprise wavelengths down to 300 nm in some embodiments.

While specific embodiments of the invention have been described above, it will be appreciated that the invention may be practiced otherwise than as described. The descriptions above are intended to be illustrative, not limiting. It will be apparent to one skilled in the art that modifications may be made to the invention as described without departing from the scope of the claims set out below.

Each feature disclosed or illustrated in the present specification may be incorporated in the invention, whether alone or in any appropriate combination with any other feature disclosed or illustrated herein.

1. An optical sensor configured to sense light in a first wavelength range in an ultraviolet spectrum, the optical sensor comprising:
a first photodiode sensitive to light in the first wavelength range and to light in a second wavelength range in the ultraviolet spectrum, wherein the second wavelength range comprises longer wavelengths than the first wavelength range, and wherein the first photodiode is configured to output a first signal in response to incident light; and
a second photodiode sensitive to light in the second wavelength range and comprising an absorption layer having an optical thickness in a range of 10 nm to 250 nm to absorb light in the first wavelength range, while being substantially transparent to light in the second wavelength range, wherein the second photodiode is configured to output a second signal in response to incident light;
wherein the optical sensor is configured to combine said first and second signals to output a signal representing a difference between the light incident on the first photodiode and the light reaching the second photodiode after passing through said absorption layer.

2. The optical sensor according to claim 1, wherein the absorption layer is a silicon nitride layer.

3. The optical sensor according to claim 1, wherein the absorption layer has a thickness in a range of 5 nm to 100 nm.

4. The optical sensor according to claim 1, further comprising a passivation layer comprising a first opening over a light sensitive region of the first photodiode and a second opening over a light sensitive region of the second photodiode, wherein the absorption layer is located in the second opening.

5. The optical sensor according to claim 4, wherein the passivation layer comprises a second silicon nitride layer.

6. The optical sensor according to claim 5, wherein a refractive index of the absorption layer is different from a refractive index of the of the second silicon nitride layer.

7. The optical sensor according to claim 4, wherein the passivation layer has a thickness greater than 200 nm.

8. The optical sensor according to claim 1, wherein the first wavelength range comprises 200 nm to 275 nm, and the second wavelength range comprises 400 nm to 1100 nm.

9. A method of making an optical sensor configured to sense light in a first wavelength range in an ultraviolet spectrum, the method comprising:
forming a first photodiode sensitive to light in the first wavelength range and to light in a second wavelength range in the ultraviolet spectrum, wherein the second wavelength range comprises longer wavelengths than the first wavelength range, wherein the first photodiode is configured to output a first signal in response to incident light; and
forming a second photodiode sensitive to light in the second wavelength range and comprising an absorption layer having an optical thickness in a range of 10 nm to 250 nm to absorb light in the first wavelength range, and to be substantially transparent to light in the second wavelength range, wherein the second photodiode is configured to output a second signal in response to incident light;
wherein the optical sensor is configured to combine said first and second signals to output a signal representing a difference between the light incident on the first photodiode and the light reaching the second photodiode after passing through said absorption layer.

10. The method according to claim 9, wherein the absorption layer is a silicon nitride layer.

11. The method according to claim 9, wherein the absorption layer has a thickness in a range of 5 nm to 100 nm.

12. The method according to claim 9, wherein the method comprises depositing the absorption layer at a deposition rate in a range of 120 nm/min and 200 nm/min.

13. The method according to claim 9, wherein the method comprises depositing the absorption layer with a Radio Frequency (RF) power in a range of 80 W to 120 W.

14. The method according to claim 9, wherein the absorption layer is provided by a reaction
SiH₄+2N₂O+He→SiₓO_{y}N_{z}+He+2H₂+N₂.

15. The method according to claim 14, wherein a ratio of SiH₄ provided to form the absorption layer is set to provide a pre-determined refractive index of the absorption layer.

16. The method according to claim 9, further comprising:
forming a passivation layer over the first and second photodiodes;
etching the passivation layer to provide a first opening over a light sensitive region of the first photodiode and a second opening over a light sensitive region of the second photodiode;
depositing the absorption layer over the passivation layer and over the first and second photodiodes; and
selectively etching the absorption layer to remove the absorption layer from the first opening while leaving the absorption layer in the second opening.

17. The method according to claim 16, wherein said forming the passivation layer comprises depositing a second silicon nitride layer.

18. The method according to claim 17, wherein the second silicon nitride layer is deposited at a rate in a range of 800 nm/min and 1000 nm/min.

19. The method according to claim 17, wherein the method comprises depositing the second silicon nitride layer with a Radio Frequency (RF) power in a range of 800 W to 1000 W.

20. The method according to claim 17, wherein a refractive index of the absorption layer is different from a refractive index of the second silicon nitride layer.

21. The method according to claim 16, wherein the passivation layer has a thickness greater than 200 nm.

22. The method according to claim 9, wherein the first wavelength range comprises 200 nm to 275 nm, and the second wavelength range comprises 400 nm to 1100 nm.
